(19) United States
(12) Patent Application Publication
(10) Pub. No.: US 2005/0038616 A1
(43) Pub. Date: Feb. 17, 2005

(54) Method and apparatus for diagnosing jitter tolerance

(75) Inventor: Manabu Sasaki, Kawasaki (JP)

Correspondence Address: ARENT FOX KINTNER PLOTKIN & KAHN, 1050 CONNECTICUT AVENUE, N.W., SUITE 400, WASHINGTON, DC, 20036, US

(73) Assignee: FUJITSU LIMITED

(21) Appl. No.: 10/910,344

(22) Filed: Aug. 4, 2004

Related U.S. Application Data
(63) Continuation of application No. PCT/JP02/00971, filed on Feb. 6, 2002.

(51) Int. Cl. G01R 13/00

(52) U.S. Cl. 702/69

(57) ABSTRACT

The present invention relates to a method for measuring jitter tolerance for diagnosis by instructing a jitter adding circuit disposed precedingly to an intended circuit block to generate jitter with a desired magnitude, monitoring at least one output signal outputted from an LSI to be evaluated for judging on whether or not the characteristic of this output signal satisfies a desired standard. It also relates to a jitter tolerance diagnostic apparatus to which this method is applied. According to the jitter tolerance diagnostic method and apparatus of the present invention, with a simple interface provided, it is possible to measure jitter tolerance of the entire LSI to be evaluated and of an intended circuit block therein.

### CROSS REFERENCE TO RELATED APPLICATION

This application is a continuation application of International Application PCT/JP02/00971, filed on Feb. 6, 2002, designating the U.S.

### BACKGROUND OF THE INVENTION

1. Field of the Invention

The present invention relates to a method and an apparatus for diagnosing jitter tolerance of an LSI such as a high-speed interconnect which is required to operate at high speed.

With the high-speed operation and high performance of a data processing unit, for example, an interface between a central processing unit and a main memory has also been demanded for operation at higher speed. In response to such a demand, a standard called InfiniBand has been established for high-speed interconnect, and products have been developed conforming to this standard.

Needless to say that the high-speed interconnect is required to have extremely high data transmission speed. In recent years mainstream products have very high transmission speed per link such as 2.5 Gbps. With a higher transmission speed, strict restriction has to be imposed on the characteristics of signals transmitted in each link. According to the InfiniBand standard tolerable jitter in an output signal Tx and an input signal Rx of the high-speed interconnect are 0.35 UI and 0.65 UI respectively. UI as a unit of jitter here means unit interval per one bit of data, and for reference, when the transmission speed is 2.5 Gbps, 1 UI is as small as 400 ps.

With the above-described situation taken into consideration, there is a need for a technique of determining, in the manufacturing process of the high-speed interconnect, whether or not each LSI has jitter tolerance satisfying the standard.

2. Description of the Related Art

FIG. 12 shows a typical configuration of an interconnect LSI.

As shown in FIG. 12, a typical interconnect LSI has a Tx block 410 that serializes and outputs input data and an Rx block 420 that parallelizes and outputs serial data. The Tx block 410 and the Rx block 420 shown in FIG. 12 respectively have clock generators 414, 424, each generating a clock signal with required cycles based on a clock signal that a PLL 401 generates based on a reference clock and supplying the clock signal to a serializer 412 and a driver 413, or to a deserializer 422 and a receiver 423.

The interconnect LSI is thus composed of elements having various functions and these elements operate in association with one another. Therefore, possible factors of deteriorating circuit characteristics of the interconnect LSI are not only individual factors relating to the individual elements such as variation in LSI fabrication process and junction temperature, but also factors to be considered in light of the association among the plural elements such as, for example, the influence that jitter appearing in the clock signal generated by the clock generator 414 provided in the Tx block 410 gives to the operation of the serializer 412 or the driver 413.

These factors should have been studied seriously. However, conventionally, since performance speed required for the interconnect LSI has not been very high, a method of using as an indicator an adjusting code of the PLL 401 provided in the interconnect LSI has been generally adopted.

This method evaluates the degree of the deterioration of the circuit characteristics in the interconnect LSI caused by the aforementioned various factors, based on a factor relating to the PLL which is assumed to represent the various factors. In other words, it uses the adjusting code of the PLL outputted via an output terminal of the interconnect LSI as an indicator of the deterioration of the circuit characteristics of the entire interconnect LSI, and it can be said that the method has been effective as a simple method.

However, as a matter of course, this method can clarify only the degree of the deterioration caused by the PLL which is one of the many elements constituting the interconnect LSI. Therefore, it is almost impossible to expect that the evaluation result obtained by the method using this adjusting code of the PLL will serve as a basis of judging whether or not the circuit characteristics of the recent high-speed interconnect LSI, in particular, the characteristics relating to output jitter and input tolerance jitter satisfy the standard such as InfiniBand.

Therefore, a method of actually measuring jitter tolerance of the high-speed interconnect LSI through the use of a measuring equipment such as a synthesizer is under consideration.

FIG. 13 shows a conceptual view of a conventional jitter tolerance measuring method.

A synthesizer 402 shown in FIG. 13 generates a reference clock with a noise added thereto and inputs the reference clock to a PLL 401 provided in an interconnect LSI. In this state, a noise measuring equipment 403 measures an amount of noise included in a signal outputted from a Tx block 410 of the interconnect LSI. The amount of the noise thus measured at an output end of the Tx block 410 and an amount of the noise added by the synthesizer 402 are related with each other, thereby evaluating jitter tolerance of the Tx block 410. Meanwhile, a noise adding equipment 404 adds a noise to a signal inputted to an Rx block 420 from the Tx block 410, and a signal monitoring equipment 405 monitors an output signal of the Rx block 420 obtained at this time. The monitor result of the signal monitoring equipment 405 and the amount of the noise added by the noise adding equipment 404 are related with each other, thereby evaluating the maximum tolerable noise amount at which the Rx block 420 can normally receive data, namely, evaluating jitter tolerance at an input end of the Rx block 420.

The application of such a jitter tolerance measuring method enables individual actual measurement of jitter tolerance of each of a Tx block and an Rx block when jitter occurs in a reference clock.

However, various measuring equipments have to be prepared as shown in FIG. 13 in order to implement this measuring method, resulting in a considerably large scale measuring system. Further, in this measuring method, since it is necessary to newly prepare extremely high-precision connectors and sockets for realizing the connection between these measuring equipments and the interconnect LSI and to avoid noise mixture caused by the connection itself for the measurement. This measuring method thus requires enormous labor and cost for implementation, which makes it very difficult for this method to be applied to total inspection or the like of mass-produced products, though it can be applied to prototype tests, sampling inspection of products, and the like.

Further, an input with jitter added thereto can be directly inputted only to the input end of the PLL 401, the Tx block 410, or the Rx block 420 as shown in FIG. 13, and therefore, even if this measuring method is applied, it is not possible to individually evaluate jitter tolerance of each portion constituting the TX block 410 or the RX block 420, though, as for a circuit portion in which the PLL 401 and the Tx block 410 or the Rx block 420 are combined, it is possible to evaluate jitter tolerance as this circuit portion.

Further, on the contrary to the improvement in the performance of the high-speed interconnect LSI, there has been no remarkable change in the magnitude of the factors deteriorating the circuit characteristics of the LSI for the past several years. In reality, the width of fine lines created in the fabrication process of circuit blocks varies, as has been heretofore, from a reference value by −60% to +50%. Junction temperature also varies by −40° C. to +50° C. from a reference value. Under such circumstances with regard to the fabrication process of the LSI, it is indispensable to develop a technique that can surely obtain jitter tolerance of each circuit block constituting the LSI for substantially all of the manufactured LSIs in order to mass-produce reliable high-speed interconnect LSIs fully satisfying the standard.

### SUMMARY OF THE INVENTION

It is an object of the present invention to evaluate jitter tolerance of each of a plurality circuit blocks forming an LSI to be evaluated by adding arbitrary jitter to an input end of an arbitrary one of the circuit blocks.

It is another object of the present invention to provide a jitter adding circuit capable of adding arbitrary jitter while maintaining performance of an LSI to be evaluated.

It is still another object of the present invention to provide a method for generating, according to a simple control code, jitter that is variable in a practical range.

It is yet another object of the present invention to evaluate jitter tolerance of each of the circuit blocks and greatly contribute to the designing of an LSI such as a high-speed interconnect LSI having an extremely narrow jitter margin by giving effective feedback thereto.

It is yet another object of the present invention to realize jitter tolerance measurement through the use of a very simple interface, thereby enabling not only a sampling inspection at a trial stage but also total inspection of mass-manufactured products to be made at practical cost.

It is yet another object of the present invention to establish the total inspection of mass-manufactured products to ensure the supply of highly reliable products. Achieving this object is immeasurably advantageous in manufacturing an LSI such as a high-speed interconnect because it is difficult to secure a sufficient jitter margin thereof.

The objects stated above are realized by a first jitter tolerance diagnostic method including the steps of: instructing, by inputting a control code thereto, a jitter adding circuit to generate a jitter of a desired magnitude, the jitter adding circuit being disposed precedingly to an intended circuit block and provided with a function of generating jitter of a magnitude designated by the control code; and monitoring at least one output signal outputted from an LSI to be evaluated and judging whether or not a characteristic of the output signal satisfies a desired standard.

According to the first jitter tolerance diagnostic method, monitoring the output signal of the LSI makes it possible to find jitter tolerance for individual circuit blocks.

The objects stated above are also realized by a second jitter tolerance diagnostic method including the steps of: selecting a complementary MOS circuit element disposed between an intended circuit block of a plurality of circuit blocks and a circuit block preceding the intended circuit block; replacing the selected complementary MOS circuit element by a jitter adding circuit that is a combination of a pMOS transistor and an nMOS transistor with a ratio of sizes changeable in accordance with an inputted ratio change code; and for diagnosis of jitter tolerance of an LSI to be evaluated, changing within a predetermined range the ratio of sizes of the pMOS transistor and the nMOS transistor which form the jitter adding circuit disposed precedingly to the intended circuit block, the predetermined range being determined based on a ratio of sizes of pMOS and nMOS transistors in the replaced complementary MOS circuit element corresponding to the jitter adding circuit; and monitoring at least one output signal outputted from the LSI to be evaluated to judge whether or not a characteristic of the output signal satisfies a desired standard.

According to such a second jitter tolerance diagnostic method, it is possible to add pseudo jitter of a desired magnitude to an input signal by changing the size ratio of the pMOS transistor and the nMOS transistor forming the jitter adding circuit that is disposed in place of an appropriate complementary MOS circuit element. It is also possible to monitor the output signals of the LSI to be evaluated, in association with the magnitude of the pseudo jitter.

Further, in order to achieve the above-mentioned objects it is effective to select a buffer or an inverter disposed between an intended circuit block and a circuit block preceding the intended circuit block in the selecting step of the second jitter tolerance diagnostic method.

According to such a jitter tolerance diagnostic method, it is able to arrange jitter adding circuits freely in an LSI to be evaluated because it is expectable that a large number of buffers or inverters are disposed as elements for mutual connection of the circuit blocks in an LSI to be evaluated.

The objects stated above are also realized by a first jitter tolerance diagnostic apparatus including: a jitter adding circuit disposed precedingly to at least one of a plurality of circuit blocks forming an LSI, for adding, to a signal received from a preceding circuit block, a jitter of a magnitude corresponding to an inputted control code and outputting the signal; a jitter controlling unit instructing, by inputting the control code thereto, the jitter adding circuits to add a jitter of a desired magnitude; and a monitoring unit monitoring an output signal outputted from the LSI to be evaluated to judge whether or not a characteristic of the output signal satisfies a desired standard.

According to the first jitter tolerance diagnostic apparatus thus structured, it is possible to find a magnitude of jitter, namely, jitter tolerance which is an upper limit characteristic of the output signal satisfying a desired standard, by monitoring the output signal of the LSI to be evaluated in association with an added jitter value. In other words, it is possible to measure jitter tolerance not only of the entire LSI to be evaluated but also of individual intended circuit blocks.

The objects stated above is also realized by a first jitter adding circuit including: a complementary MOS circuit element formed of a pMOS transistor of a predetermined size and an nMOS transistor of a predetermined size different from that of the pMOS transistor; and a size ratio changing unit changing, according to an inputted control code, a ratio of sizes of the pMOS transistor and the nMOS transistor which contribute to the formation of the complementary MOS circuit element.

According to such a first jitter adding circuit, it is able to use output signals of the complementary MOS circuit element for jitter tolerance diagnosis by changing waveforms of the output signals to add pseudo jitter of a desired magnitude thereto.

The objects stated above are also realized by a second jitter adding circuit including a buffer or an inverter having a number k of nMOS transistors which are connected in parallel to a source terminal of a pMOS transistor. The ratio of sizes of at least one of the number k of nMOS transistors and the pMOS transistor is a value smaller than a reference value for the buffer or the inverter to operate optimally. The ratio of a total of sizes of all the nMOS transistors and the pMOS transistor is a value equal to or larger than the reference value. The second jitter adding circuit may also include a size ratio changing unit having: a number k of switches disposed in correspondence with the number k of nMOS transistors, each for determining whether or not its corresponding nMOS transistor is allowed to contribute to the formation of the buffer or the inverter; and a switch controlling unit selecting appropriate switch/switches from the switches according to an inputted control code and allowing an nMOS transistor corresponding to the selected switch(es) to contribute to the formation of the buffer or the inverter.

The size ratio changing unit as structured above enables the jitter adding circuit to add a desired jitter during the jitter tolerance diagnosis, and to operate as a buffer or an in inverter of sufficient performance after the jitter tolerance diagnosis.

The objects state above are also realized by a second jitter tolerance diagnostic apparatus similar to the first jitter tolerance diagnostic apparatus except that the jitter adding circuit includes a number m of switches and a buffer or an inverter provided with a fixed transistor and a number m of variable transistors and that the jitter controlling unit includes a control code generating unit and a selecting unit. The fixed transistor is connected in series to the pMOS transistor forming the buffer or the inverter and is an nMOS transistor having a predetermined size S contributing to a function of the buffer or the inverter. The number m of variable transistors are nMOS transistors of a size Sᵢ(i=1 to m) and connected in parallel to the fixed transistor. The number m of switches are disposed in correspondence with the number m of variable transistors and each determines according to a control signal whether or not to allow its corresponding variable transistor to contribute to the formation of the buffer or the inverter. The control code generating unit generates a control signal of m bits according to a desired jitter value, and the selecting unit selects a circuit block from the at least one of plurality of circuit blocks and inputs control signals of bits forming the control codes, respectively to the number m of switches provided in a jitter adding circuit corresponding to the selected circuit block.

Such a second jitter tolerance diagnostic apparatus is able to discretely change the magnitude of pseudo jitter to be added, according to the control signals of m bits.

Moreover, in order to achieve the above-described objects, the jitter adding circuit in the second jitter tolerance diagnostic apparatus may also be effectively configured to have the number m of variable transistors of a size Sᵢ(i=1 to m)=2ⁱ⁻¹×S. The jitter adding circuit provided with the variable transistors thus structured can discretely change the sizes of the nMOS transistors contributing to the formation of the buffer or the inverter by S in a range from the minimum value S corresponding to the size of the fixed transistor up to the maximum value 2m×S, to add a jitter to an input signal according to the changed size.

### BRIEF DESCRIPTION OF THE DRAWINGS

The nature, principle, and utility of the invention will become more apparent from the following detailed description when read in conjunction with the accompanying drawings in which like parts are designated by identical reference numbers, in which:

FIG. 1(a) and FIG. 1(b) are charts showing the principles of a jitter tolerance diagnostic method according to the present invention;

FIG. 2 is a block diagram showing the principle of a first jitter tolerance diagnostic apparatus according to the present invention;

FIG. 3 is a block diagram showing the principle of a jitter adding circuit according to the present invention;

FIG. 4 is a block diagram showing the principle of a second jitter tolerance diagnostic apparatus according to the present invention;

FIG. 5 is a diagram showing an embodiment of the jitter tolerance diagnostic apparatus according to the present invention;

FIG. 6 is a diagram showing the configuration of a jitter adding circuit in detail;

FIG. 7 is a flowchart showing the operation of the jitter tolerance diagnostic apparatus;

FIG. 8 is an explanatory chart of a jitter adding operation;

FIG. 9 is a diagram showing another embodiment of the jitter adding circuit;

FIG. 10 is a diagram showing an arrangement example of the jitter adding circuits;

FIG. 11 is a diagram showing still another embodiment of the jitter adding circuit;

FIG. 12 is a diagram showing a typical configuration of an interconnect LSI; and

FIG. 13 is a conceptual diagram of a conventional jitter tolerance measuring method.

### DESCRIPTION OF THE PREFERRED EMBODIMENTS

[Principles]

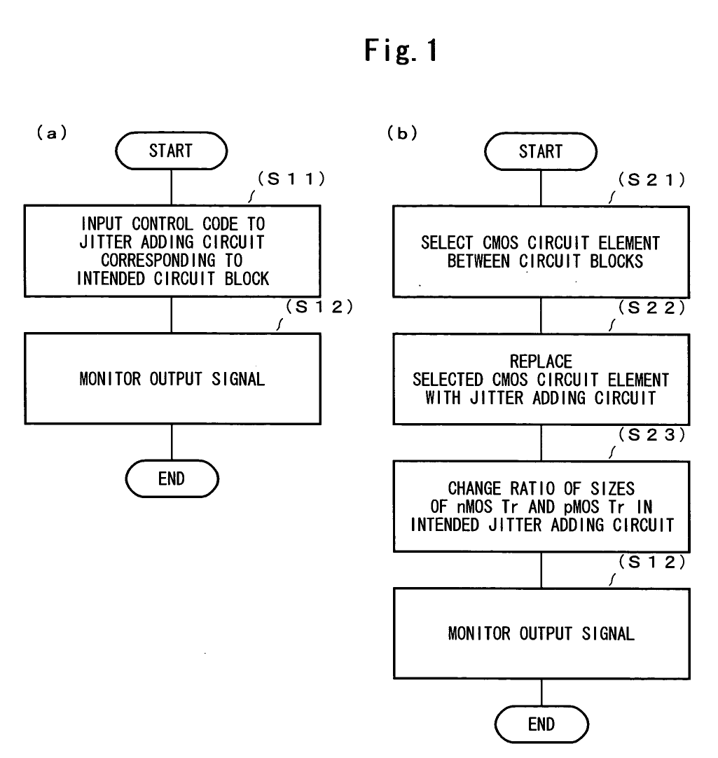

First, the principles of the jitter tolerance diagnostic method according to the present invention will be described with reference to FIG. 1(a) and FIG. 1(b). FIG. 1(a) and FIG. 1(b) show the principles of the jitter tolerance diagnostic method according to the present invention.

A first jitter tolerance diagnostic method shown in FIG. 1(a) includes an instructing procedure (S11) and a monitoring procedure (S12).

The principle of the first jitter tolerance diagnostic method according to the present invention is as follows.

The instructing procedure (S11) instructs, by inputting a control code, a jitter adding circuit to generate jitter with a desired magnitude, the jitter adding circuit being disposed precedingly to an intended circuit block. The monitoring procedure (S12) monitors at least one output signal outputted from an LSI to be evaluated and judges whether or not the characteristic of this output signal satisfies a desired standard.

The operation of the first jitter tolerance diagnostic method thus structured is as follows.

The instructing procedure (S11) inputs an appropriate control code to a jitter adding circuit disposed precedingly to an intended circuit block, so that a signal including jitter with a desired magnitude is inputted to the circuit block succeeding this jitter adding circuit. Further, an output signal of an LSI is monitored by the monitoring procedure (S12) while the magnitude of the jitter generated by the jitter adding circuit is varied by the instructing procedure (S11), so that it is possible to find the magnitude of jitter corresponding to the limit at which the characteristic of the output signal satisfies a desired standard, namely, jitter tolerance.

A second jitter tolerance diagnostic method shown in FIG. 1(b) includes a selecting procedure (S21), a replacing procedure (S22), a size ratio changing procedure (S23), and a monitoring procedure (S12).

The principle of the second jitter tolerance diagnostic method according to the present invention is as follows.

The selecting procedure (S21) selects a complementary MOS circuit element disposed between an intended circuit block and a circuit block preceding the intended circuit block. The replacing procedure (S22) replaces the selected buffer or inverter by a jitter adding circuit that is a circuit in which a pMOS transistor and an nMOS transistor whose size ratio is variable according to an inputted ratio change code are combined and that is a circuit exhibiting a function equivalent to that of the selected complementary MOS circuit element when the size ratio is fixed to an appropriate value. When jitter tolerance of an LSI to be evaluated is measured, the size ratio changing procedure (S23) changes the size ratio of the pMOS transistor and the nMOS transistor forming the jitter adding circuit precedingly disposed to an intended circuit block within a predetermined range that is determined based on the size ratio at which this jitter adding circuit exhibits the function equivalent to that of the replaced complementary MOS circuit element. The monitoring procedure (S12) monitors at least one output signal outputted from the LSI to be evaluated to judge whether or not the characteristic of this output signal satisfies a desired standard.

The operation of the second jitter tolerance diagnostic method as structured above is as follows.

At the manufacturing stage of the LSI to be evaluated, the replacing procedure (S22) replaces the complementary MOS circuit element selected by the selecting procedure (S21) by the jitter adding circuit including the pMOS transistor and the nMOS transistor whose size ratio is variable. When the jitter tolerance of the LSI to be evaluated is measured, the size ratio changing procedure (S23) changes the size ratio of the pMOS transistor and the nMOS transistor in the jitter adding circuit corresponding to an intended circuit block, thereby varying the rising time or the falling time of a signal inputted to the intended circuit block via this jitter adding circuit, according to the ratio of the changed size ratio and the reference size ratio. Such variation of the rising time or the falling time of the input signal is equivalent to the addition of pseudo jitter having the magnitude corresponding to the magnitude of this variation to the input signal. The monitoring procedure (S12) monitors the output signal of the LSI to be evaluated, in association with the magnitude of the pseudo jitter thus added.

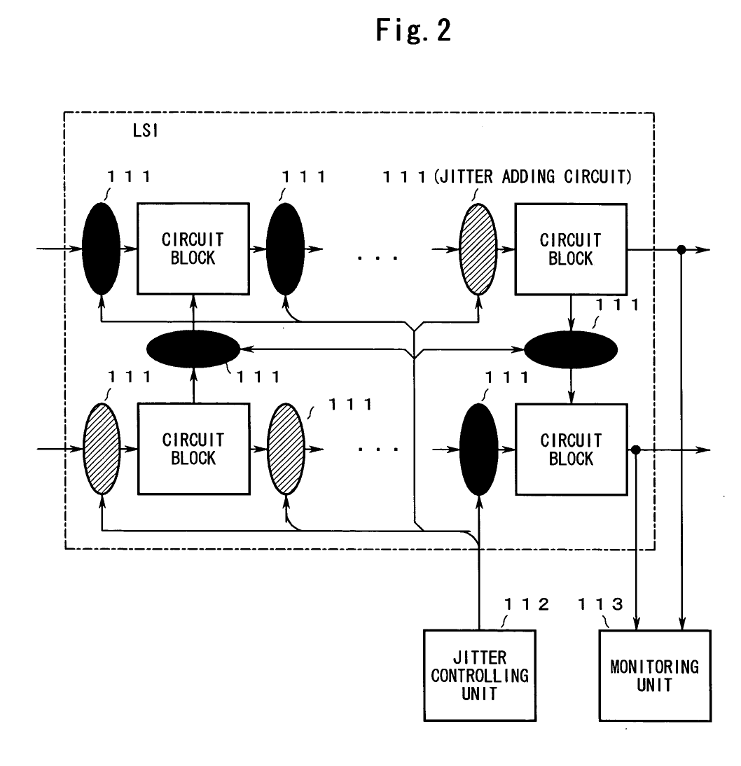

Next, the principle of a first jitter tolerance diagnostic apparatus according to the present invention will be described with reference to FIG. 2.

FIG. 2 is a block diagram showing the principle of the first jitter tolerance diagnostic apparatus according to the present invention

The first jitter tolerance diagnostic apparatus shown in FIG. 2 is composed of jitter adding circuits 111, a jitter controlling unit 112, and a monitoring unit 113.

The principle of the first jitter tolerance diagnostic apparatus according to the present invention is as follows.

Each of the jitter adding circuits 111, which is disposed precedingly to at least one circuit block of a plurality of circuit blocks forming an LSI, adds jitter with the magnitude corresponding to an inputted control code to a signal received from a preceding circuit block and inputs this signal to a succeeding circuit block. The jitter controlling unit 112 instructs, by inputting the control code, the jitter adding circuit 111 corresponding to one of the plural circuit blocks forming the LSI, to add jitter with a desired magnitude. The monitoring unit 113 monitors at least one output signal outputted from the LSI to be evaluated to judge whether or not the characteristic of this output signal satisfies a desired standard.

The operation of the jitter tolerance diagnostic apparatus thus structured is as follows.

When jitter tolerance of an intended circuit block is diagnosed, the jitter controlling unit 112 instructs, by inputting the control code, the jitter adding circuit 111 disposed precedingly to this circuit block to add jitter with an appropriate magnitude. For example, the jitter controlling unit 112 inputs the control code to the jitter adding circuit 1111, thereby instructing it to add jitter with the magnitude within a predetermined range, and the monitoring unit 113 monitors the output signal of the LSI to be evaluated in association with a jitter value added based on the control code, so that it is possible to find the magnitude of the jitter corresponding to the limit at which the characteristic of this output signal satisfies a desired standard, namely, jitter tolerance.

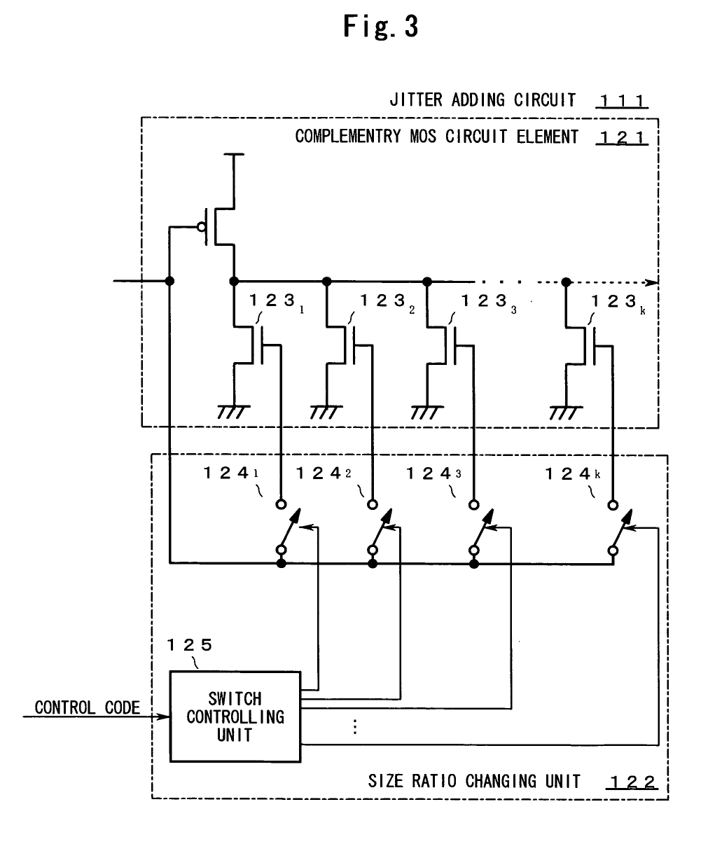

Further, the principle of the jitter adding circuit according to the present invention will be described with reference to FIG. 3.

FIG. 3 is a diagram showing the principle of the jitter adding circuit according to the present invention.

The jitter adding circuit shown in FIG. 3 is composed of a complementary MOS circuit element 121 and a size ratio changing unit 122.

The principle of the jitter adding circuit according to the present invention is as follows.

The complementary MOS circuit element 121 is formed of a pMOS transistor having a predetermined size and nMOS transistors each having a predetermined size different from the size of the pMOS transistor. The size ratio changing unit 122 changes the size ratio of the pMOS transistor and the nMOS transistors contributing to the formation of the complementary MOS circuit element 121 according to the inputted control code.

The operation of the jitter adding circuit as structured above is as follows.

The size ratio changing unit 122 separates a portion corresponding to the jitter value designated by the control code from the pMOS transistor or the nMOS transistors that should form the complementary MOS circuit element 121, to thereby change the ratio of the pMOS transistor and the nMOS transistors that practically form the complementary MOS circuit element 121. When a signal outputted from a preceding circuit block is inputted to such a jitter adding circuit 111, obtained is an output signal with a waveform different from that obtained when the size ratio of the pMOS transistor and the nMOS transistors is an reference value for them to function as the complementary MOS circuit element 121. The change in the size ratio of the pMOS nMOS transistors from the reference value makes shift the rising time or falling time of an output signal from the complementary MOS circuit element 121 from one that it is supposed to be when the size ratio is a reference value. The shift in the rising or falling time will be jitter occurring in the output signal from this jitter adding circuit 111 inputted to the circuit block. In other words, shifting the size ratio of the pMOS transistor and the nMOS transistors from the reference value makes it possible to add pseudo jitter of a magnitude corresponding to the shift in the size ratio, to the signal that is inputted to an intended circuit block via the jitter adding circuit 210.

Further, the principle of the size ratio changing unit according to the present invention will be described with reference to FIG. 3.

Note that when the jitter adding circuit 111 includes the complementary MOS circuit element 121 that is a buffer or an inverter including k pieces of nMOS transistors 123, the size ratio changing unit 122 shown in FIG. 3 may include k pieces of switches 124 and a switch controlling unit 125.

In the size ratio changing unit 122 thus structured, the k pieces of nMOS transistors 123 are connected in parallel to a source terminal of the pMOS transistor. The ratio of the size of at least one of the nMOS transistors 123 to the size of the pMOS transistor is a value smaller than the reference value for the buffer or the inverter to optimally function. The ratio of a total of the sizes of all the nMOS transistors 123 to the pMOS transistor is a value equal to or larger than the reference value. Further, in such a size ratio changing unit, the k pieces of switches 124 are disposed to correspond to the k pieces of nMOS transistors 123 and each determines whether or not to allow the corresponding nMOS transistor 123 to contribute to the buffer or the inverter. The switch controlling unit 125 selects one or more appropriate switches from the switches 124 according to the inputted control code, to have the nMOS transistor 123 corresponding to the selected switch 124 contribute to the formation of the buffer or the inverter.

The operation of the size ratio changing unit as structured above is as follows.

The switch controlling unit 125 controls the k pieces of switches 124 according to the control code, thereby having the nMOS transistors 123 selectively contribute to the formation of the buffer or inverter that is the complementary MOS circuit element 121. By this operation the size ratio of the nMOS transistors to the pMOS transistor changes from a value smaller than the reference value to a value equal to or larger than the reference value, so that the jitter can be added to the signal in accordance with the changed size ratio to input the jitter-added signal to a succeeding circuit block.

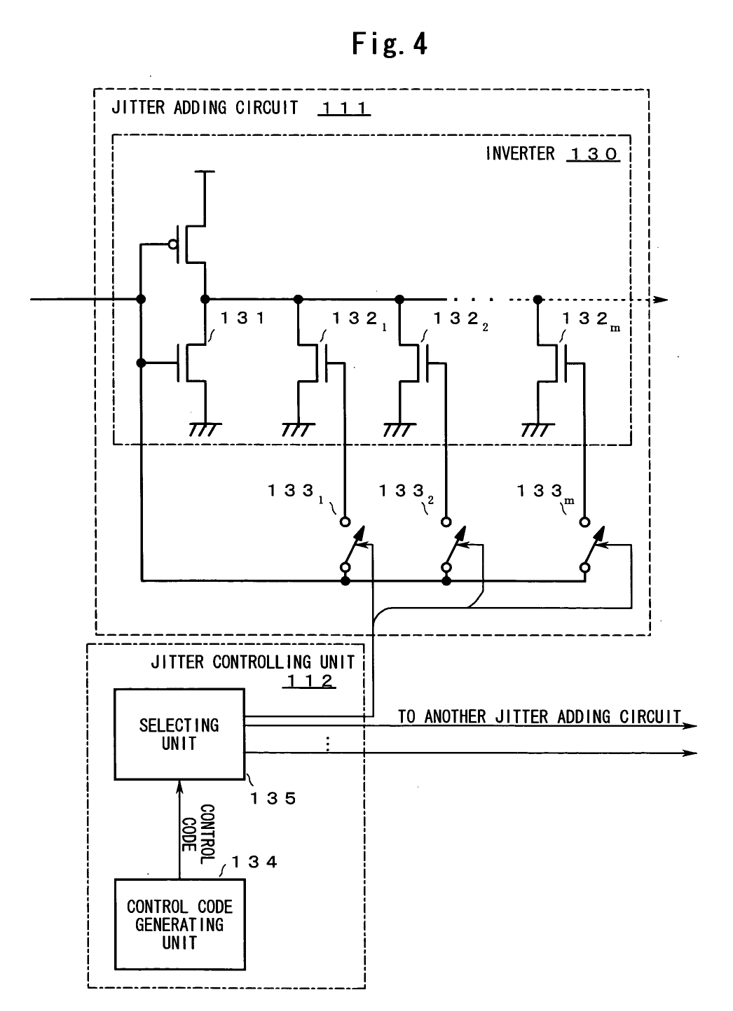

Further, the principle of a second jitter tolerance diagnostic apparatus according to the present invention will be described with reference to FIG. 4.

FIG. 4 is a diagram showing the principle of the second jitter tolerance diagnostic apparatus according to the present invention.

The second jitter tolerance diagnostic apparatus shown in FIG. 4 is composed of: a jitter adding circuit 111 including a buffer or inverter 130 and m pieces of switches 133, the buffer or inverter 130 being provided with a fixed transistor 131 and m pieces of variable transistors 132; and a jitter controlling unit 112 including a control code generating unit 134 and a selecting unit 135.

The principle of the second jitter tolerance diagnostic apparatus according to the present invention is as follows. Note that FIG. 4 shows a circuit where the jitter adding circuit 111 is formed based on the inverter.

The fixed transistor 131 provided in the jitter adding circuit 111 is connected in series to the pMOS transistor included in the buffer or inverter 130, and contributes to the function of the buffer or inverter 130 as an nMOS transistor having a predetermine size S. The m pieces of variable transistors 132 provided in the jitter adding circuit 111 are nMOS transistors having sizes Sᵢ(i=1 to m) respectively and connected in parallel to the fixed transistor 131. The m pieces of switches 133 provided in the jitter adding circuit 111 are disposed to correspond to the m pieces of variable transistors 132 and each determines according to the control code whether or not an input signal voltage is to be applied to a gate terminal of the corresponding variable transistor 132. The control code generating unit 134 provided in the jitter controlling unit 112 generates the control code of m bits according to a desired jitter value.

The selecting unit 135 provided in the jitter controlling unit 112 inputs, as control signals to the respective switches 133, signals of the respective bits forming the control code to m pieces of the switches 133 provided in the intended jitter adding circuit 111.

The operation of the jitter tolerance diagnostic apparatus as structured above is as follows.

The selecting unit 135 inputs respective bits of the control code generated by the control code generating unit 134 to the m pieces of switches 133 provided in the intended jitter adding circuit 111. According to these input bits, ON/OFF of the respective switches 133 is determined. Changing the combinations of ON/OFF of these switches 133 changes the combinations of their corresponding variable transistors 132, so that it is possible to discretely change the total of sizes of all of the nMOS transistors from a minimum value S equivalent to the size of the fixed transistor 131, to a maximum value S+ΣSᵢ(i=1 to m) which is a value when all of the variable transistors 132 contribute to the formation of the buffer or inverter 130. Along with the change in the total sizes of the nMOS transistor, the size ratio of the pMOS and nMOS transistors changes.

Further, m pieces of the variable transistors 132 provided in the jitter adding circuit 111 shown in FIG. 4 may be of the sizes Sᵢ(i=1 to m)=2ⁱ⁻¹×S respectively.

The operation of the variable transistors as structured above is as follows.

According to the combination of ON/OFF of the switches 133, the corresponding combination of the variable transistors 132 contributes to the formation of the buffer or inverter 130, and therefore, the size of the nMOS transistors contributing to the formation of the buffer or inverter 130 discretely varies by S in the range from the minimum value S corresponding to the size of the fixed transistor 131 to the maximum value 2m×S.

[Embodiments]

Hereinafter, the preferable embodiment of the jitter tolerance diagnostic apparatus according to the present invention will be described.

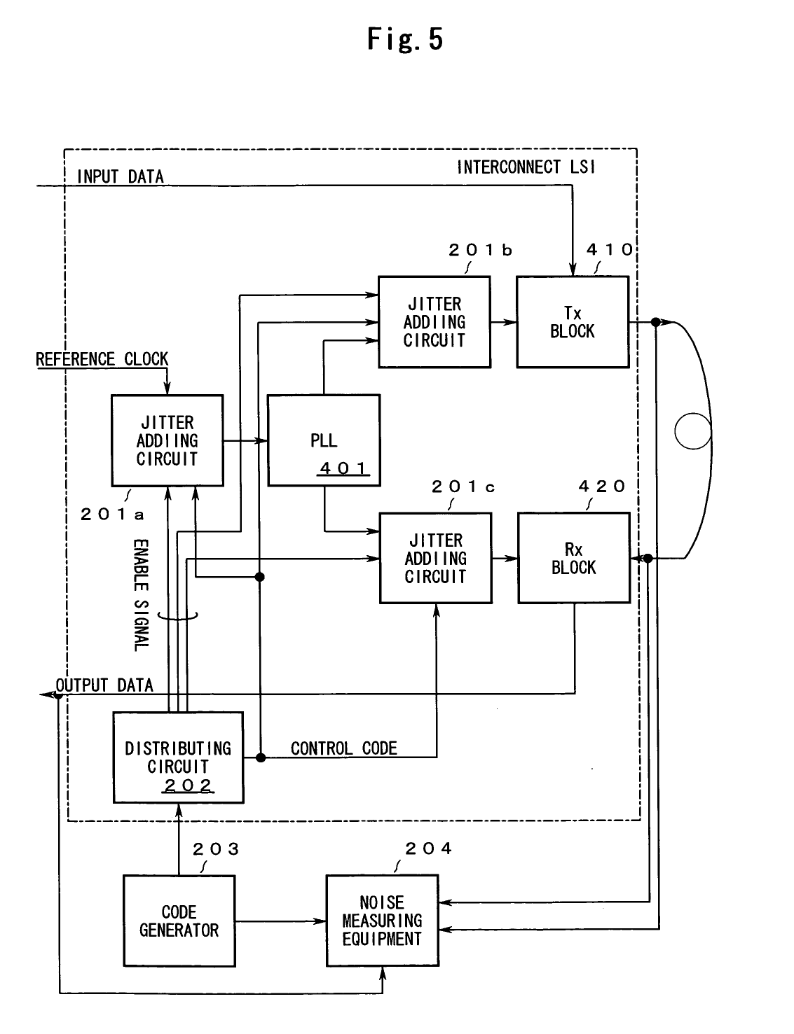

FIG. 5 shows an embodiment of the jitter tolerance diagnostic apparatus according to the present invention.

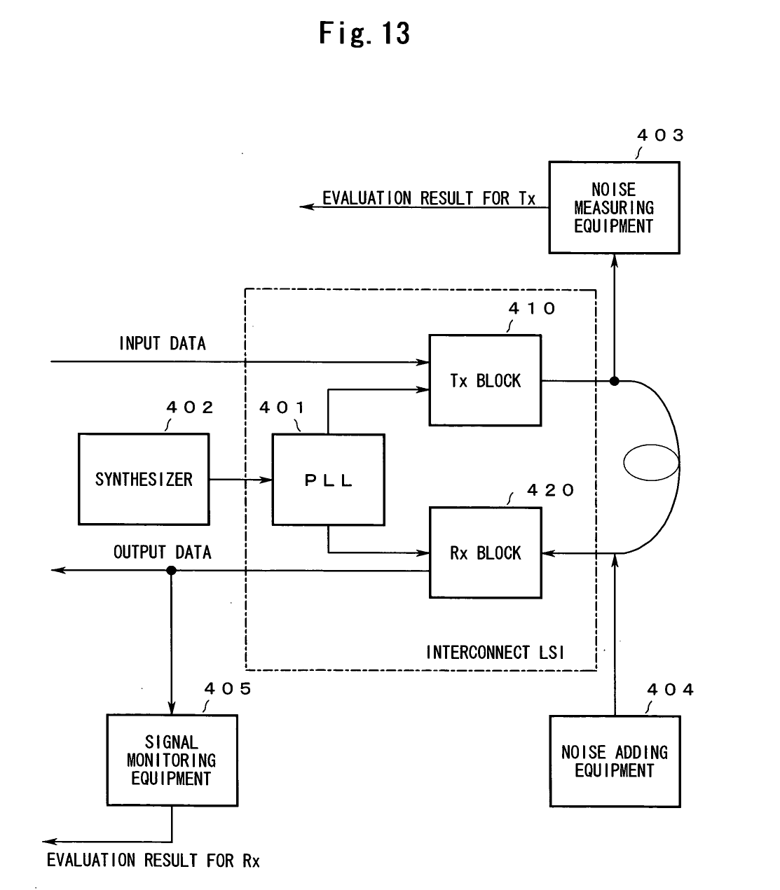

Note that the same reference numerals and symbols are used to designate portions shown in FIG. 5 that are equivalent to the portions shown in FIG. 13, and description thereof will be omitted.

In an interconnect LSI shown in FIG. 5, a reference clock is inputted to a PLL 401 via a jitter adding circuit 201a. A clock signal generated by this PLL 401 is inputted to a Tx block 410 and an Rx block 420 via jitter adding circuits 201b, 201c respectively. Further, in the interconnect LSI shown in FIG. 5, a distributing circuit 202 generates enable signals based on a select code externally inputted thereto and inputs the corresponding enable signals to the aforesaid three jitter adding circuits 201a, 201b, 201c respectively. The distributing circuit 202 also inputs a control code externally inputted thereto to the aforesaid three jitter adding circuits 201a, 201b, 201c according to the later-described procedure. Hereinafter, the jitter adding circuits 201a, 201b, 201c, when collectively called, will be referred to simply as the jitter adding circuits 201.

A code generator 203 shown in FIG. 5 generates the control code indicating a numerical value within a predeteremined range and the select code indicating one of the aforesaid three jitter adding circuits 201 according to the later-described procedure, and inputs the control code and the select code to the distributing circuit 202 via an input terminal for control information provided in the interconnect LSI. A noise measuring equipment 204 shown in FIG. 5 measures the magnitude of a noise component mixed in a data signal outputted from the Tx block 410 or a data signal outputted from the Rx block 420, and outputs the measurement result in association with the control code and the select code received from the code generator 203.

Next, the configuration of the jitter adding circuit will be described in detail.

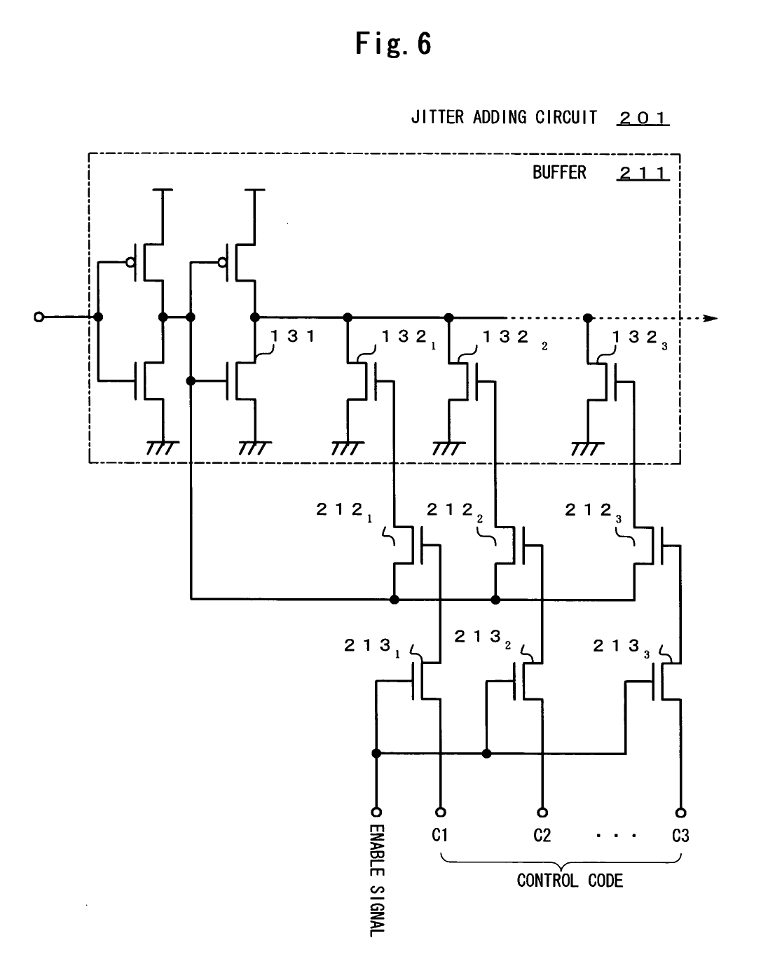

FIG. 6 shows the configuration of the jitter adding circuit in detail.

In the jitter adding circuit 201 shown in FIG. 6, a buffer 211 is composed of one inverter formed of a pMOS transistor and an nMOS transistor, and another inverter formed by connecting in parallel fixed transistor 131 and three variable transistors 132₁ to 132₃ to a source terminal of a pMOS transistor. The fixed transistor 131 and m pieces of the variable transistors 132₁ to 132₃ shown in FIG. 6 are all nMOS transistors, and a source terminal of each of these nMOS transistors is grounded. Further, sizes Sᵢ of the respective three variable transistors 132₁ to 132₃ are expressed by the expression (1), using a size S of the fixed transistor 131.
Sᵢ=2ⁱ⁻¹×S (1)

Note that the size S of the fixed transistor 131 may be, for example, one fourth of a size Sp of the pMOS transistor.

An output signal of the preceding inverter is inputted to a gate terminal of the fixed transistor 131 while the output signal of the preceding inverter is inputted to gate terminals of the three variable transistors 132₁ to 132₃ via MOS transistors 212₁ to 212₃. Further, in FIG. 6, drain terminals of MOS transistors 213₁ to 213₃ are connected to gate terminals of the MOS transistors 212₁ to 212₃ respectively, and when the MOS transistors 213₁ to 213₃ are turned on in response to the enable signals, signal voltages according to corresponding bit values of the control code are applied to the gate terminals of the MOS transistors 212₁ to 212₃.

Hereinafter, the variable transistors 132₁ to 132₃, the MOS transistors 212₁ to 212₃, and the MOS transistors 213₁ to 213₃, when collectively called, are referred to simply as the variable transistors 132, the MOS transistors 212, and the MOS transistors 213 respectively.

The correspondence relation between the units shown in FIG. 2, FIG. 3, and FIG. 4 and the portions shown in FIG. 5 and FIG. 6 will be shown below.

The jitter adding circuits 201 shown in FIG. 5 correspond to the jitter adding circuits 111 shown in FIG. 2. The PLL 401, the Tx block 410, and the Rx block 420 shown in FIG. 5 correspond to the circuit blocks shown in FIG. 2 respectively. The distributing circuit 202 and the code generator 203 shown in FIG. 5 correspond to the jitter controlling unit 112 shown in FIG. 2. The noise measuring equipment 204 shown in FIG. 5 corresponds to the monitoring unit 113 shown in FIG. 2. The MOS transistors 212 shown in FIG. 6 correspond to the switches 124 shown in FIG. 3 or the switches 133 shown in FIG. 4. The MOS transistors 213 shown in FIG. 6 correspond to the switch controlling unit 125 shown in FIG. 3. Further, the MOS transistors 213 shown in FIG. 6 operate according to the enable signals generated by the distributing circuit 202 shown in FIG. 5, so that the function of the selecting unit 125 shown in FIG. 4 is realized. The code generator 203 shown in FIG. 5 corresponds to the control code generating unit 124 shown in FIG. 4.

Note that the jitter adding circuits 201 having the structure shown in FIG. 6 are assembled in the interconnect LSI shown in FIG. 5 at the manufacturing stage.

In the typical design of the interconnect, a plurality of stages of inverters or buffers are often disposed between the PLL 401 and the Tx block 410 or the Rx block 420 shown in FIG. 13. Therefore, the jitter adding circuits 201 shown in FIG. 5 can be considered as those selectively replacing the inverters or buffers that are disposed precedingly to the PLL 401, the Tx block 410, or the Rx block 420 in such typical design. This means that the selecting procedure (S21) and the replacing procedure (S22) shown in FIG. 1(b) have been already completed at the manufacturing stage of the interconnect LSI shown in FIG. 5.

Next, the operation of the jitter tolerance diagnostic apparatus shown in FIG. 5 will be described.

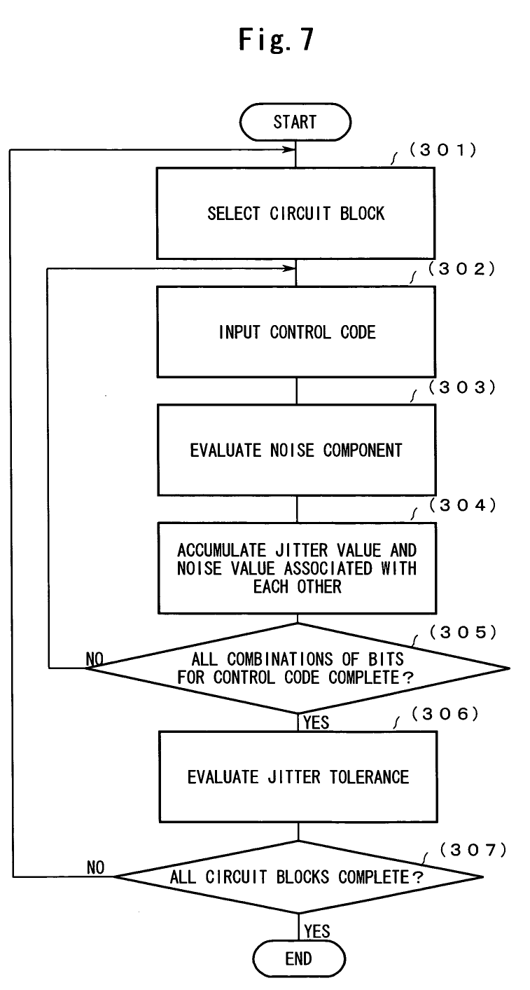

FIG. 7 shows a flowchart of the operation of the jitter tolerance diagnostic apparatus.

Refer to FIG. 5 to FIG. 7 when necessary in the following description.

The code generator 203 shown in FIG. 5 first selects one of the circuit blocks to which the jitter adding circuit 201 is disposed precedingly and inputs to the distributing circuit 202 the select code indicating the jitter adding circuit 201 corresponding to the selected circuit block (Step 301). Next, the code generator 203 generates a control code of 3 bits representing the numerical values from “0” to “2³−1” in sequence and inputs the control code to each of the jitter adding circuits 201 via the distributing circuit 202 (Step 302).

For example, upon selection of the Tx block 410, the select code indicating the corresponding jitter adding circuit 201b is inputted to the distributing circuit 202 at Step 301. The distributing circuit 202 generates the enable signal to validate a size ratio changing operation by the jitter adding circuit 201b, and this enable signal is inputted to the jitter adding circuit 201b. In response to the input of this enable signal, the MOS transistors 213 (see FIG. 6) provided in the jitter adding circuit 201b are turned on, so that voltages corresponding to the respective bits of the control code generated by the code generator 203 are applied to the gate terminals of the corresponding MOS transistors 212 at Step 302.

Consequently, the MOS transistors 212 corresponding to the bits with the logic “1”, out of the bits forming the control code, are turned on, thereby inputting to the gate terminals of the corresponding variable transistors 132a voltage value corresponding to the above-described input signal which is inputted commonly to the gate terminal of the nMOS transistor 212. In this manner, according to the control code, the predetermined variable transistors 132 are made to contribute as part of the nMOS transistors forming the buffer 211 together with the fixed transistor 131, so that the size ratio of the pMOS transistor and the nMOS transistors contributing to the formation of the buffer 211 is changed.

For example, when bits C1, C2, C3 forming the control code all have the logic “0”, all the variable transistors 132 are separated from an input signal and only the fixed transistor 131 contributes to the formation of the buffer 211. In this case, the ratio of the size Sp of the pMOS transistor complementarily coupled to the fixed transistor 131 and the size S of the fixed transistor 131 is the size ratio of the pMOS transistor and the nMOS transistors contributing to the formation of the buffer 211. Here, when the size S of the fixed transistor 131 is one fourth of the size Sp of the pMOS transistor, the size ratio of the pMOS transistor and the nMOS transistors contributing to the formation of the buffer 211 is 4:1 according to the input of the aforesaid control code, which is greatly different from the size ratio (2:1) in a typical buffer formed of CMOS.

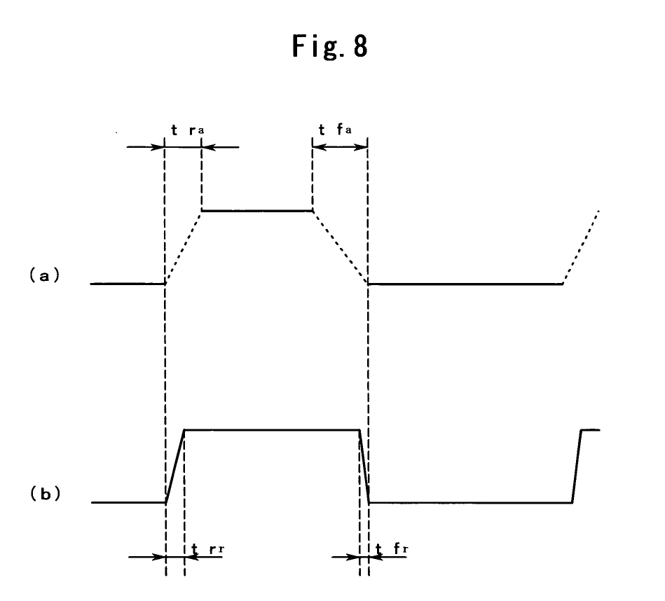

When the size ratio of the pMOS transistor and the nMOS transistors contributing to the formation of the buffer 211 is thus deviated from the optimum size ratio for the buffer 211 to function as a buffer, it naturally gives an influence to an output signal of this buffer 211. Specifically, as shown by a signal waveform denoted by the reference symbol (a) in FIG. 8, a rising time trₐ and a falling time tfₐ in the output signal of this buffer 211 are deviated from corresponding values trᵣ and tfᵣ in a reference signal waveform (denoted by the reference symbol (b) in FIG. 8) that is obtained when the buffer 211 optimally functions as a buffer. Accordingly, a duty ratio of the output signal of this buffer 211 also changes according to the deviation of the rising time and the falling time from the reference values. Such deviation in duty ratio is equivalent to jitter generated by the buffer 211 when seen from a succeeding circuit block. Here, the magnitude of the deviation of thus changed size ratio from the reference size ratio is mutually correlated with a change amount (namely, a jitter value) of the duty ratio caused by this deviation. Therefore, by changing the size ratio of the pMOS transistor and the nMOS transistors contributing to the formation of the buffer 211, jitter with the magnitude corresponding to the deviation in size ratio can be added to the input signal given to the buffer 211 and this input signal can be inputted to a succeeding circuit block (for example, the Tx block 410).

A signal outputted from the Tx block 410 in response to the input of such a signal with the jitter added thereto is inputted to the noise measuring equipment 204 via an output terminal provided in the interconnect LSI (see FIG. 5). In response to this input, the noise measuring equipment 204 measures the magnitude of a noise component included in this output signal (Step 303). Next, the noise measuring equipment 204 accumulates, as part of the measurement result on the circuit block corresponding to the select code received from the code generator 203, a noise value obtained at Step 303 and the jitter value corresponding to the control code received from the code generator 203, getting them in association with each other (Step 304). Note that the correspondence relation between the control code and the jitter value may be found in advance based on the relation between the size ratio corresponding to the control code and the jitter value.

Next, the code generator 203 judges whether or not all the control codes have been generated (Step 305), and if there still remains the control code to be generated (“NO” at Step 305), it returns to Step 302 to generate the next control code and input the control code to the distributing circuit 202.

In this manner, the code generator 203 generates all the control codes generatable from the combinations of the 3 bits, and inputs the control codes to the jitter adding circuit 201 via the distributing circuit 202 in sequence. Accordingly, the size ratio of the pMOS transistor and the nMOS transistors contributing to the formation of the buffer 211 in this jitter adding circuit 201 is discretely changed within a range from 4:1 corresponding to the control code “000” to 1:2 corresponding to the control code “111”, so that it is possible for the jitter adding circuit 201 to add the jitter corresponding to each size ratio to the input signal and give this input signal to the Tx block 410. Then, while the jitter corresponding to each size ratio is added, the noise measuring equipment 204 measures the magnitude of the noise component included in the output signal of the Tx block 410 and sequentially accumulates the noise component in association with the jitter value.

When the measurement on all the control codes is thus completed (“YES” at Step 305), the noise measuring equipment 204 examines the change of the magnitude of the noise component corresponding to the change of the jitter value, thereby finding the maximum jitter value at which the magnitude of the noise component does not exceed the limit defined by the standard, namely, jitter tolerance (Step 306).

Thereafter, the code generator 203 judges whether or not the processing on all the circuit blocks has been completed (Step 307), and if “NO”, returns to Step 301 to start the process on a new circuit block, while if “YES”, finishes the measurement process of the jitter tolerance.

As described above, according to the jitter tolerance diagnostic apparatus of the present invention, the jitter adding circuits assembled in the LSI to be evaluated are operated according to the control codes, so that the signal to which jitter with a desired magnitude is added is inputted to an intended circuit block, which makes it possible to individually find jitter tolerance for this circuit block.

Here, no expensive device such as a synthesizer for inputting a signal including jitter to an LSI to be evaluated or no high-precision interface for faithfully transmitting an external signal to the LSI to be evaluated is necessary. The jitter tolerance diagnostic apparatus according to the present invention can perform the measurement by provision of only the code generator 203 generating the simple control code and select code and the noise measuring equipment 204. For an interface between these devices and an LSI to be evaluated, a connector or socket with such a degree of precision that the LSI has when actually mounted and used will suffice. Thus, in comparing manpower and cost for applying the jitter tolerance diagnostic apparatus according to the present invention and devices and interfaces according to the conventional measuring method shown in FIG. 13, the former is far more cost and labor effective than the latter. Therefore, the jitter tolerance diagnostic apparatus of the present invention can realize the total inspection of mass-produced high-speed interconnect LSIs.

Incidentally, since the jitter adding circuit as shown in FIG. 6 is integratable to substantially the same size as the size of a typical buffer or inverter, it is fully possible to mount it in place of a buffer or inverter that is disposed in the design of an original interconnect LSI. Further, while the interconnect LSI is in operation, if, in each of the jitter adding circuits 201, the appropriate variable MOS transistors 132 contribute to the formation of the buffer 211 to realize the optimum size ratio for allowing the function as a typical buffer, the replacement of the original buffer by the jitter adding circuit 201 does not impair the performance of the interconnect LSI.

As is well known, a large number of buffers and inverters are disposed on the boundaries of circuit blocks in a large scale integrated circuit typified by an interconnect LSI. Therefore, when the jitter adding circuit is structured based on the structure of the buffer or inverter, it is possible to improve especially the degree of freedom in the arrangement of the jitter adding circuits.

Further, a circuit element to which the aforesaid jitter adding function is incorporated may be a complementary MOS circuit element formed of the combination of the pMOS transistor and the nMOS transistors, and thus, it is not limited to an inverter having the structure shown in FIG. 3 or a buffer having the structure shown in FIG. 6. For example, the jitter adding function can be incorporated in a complementary differential buffer.

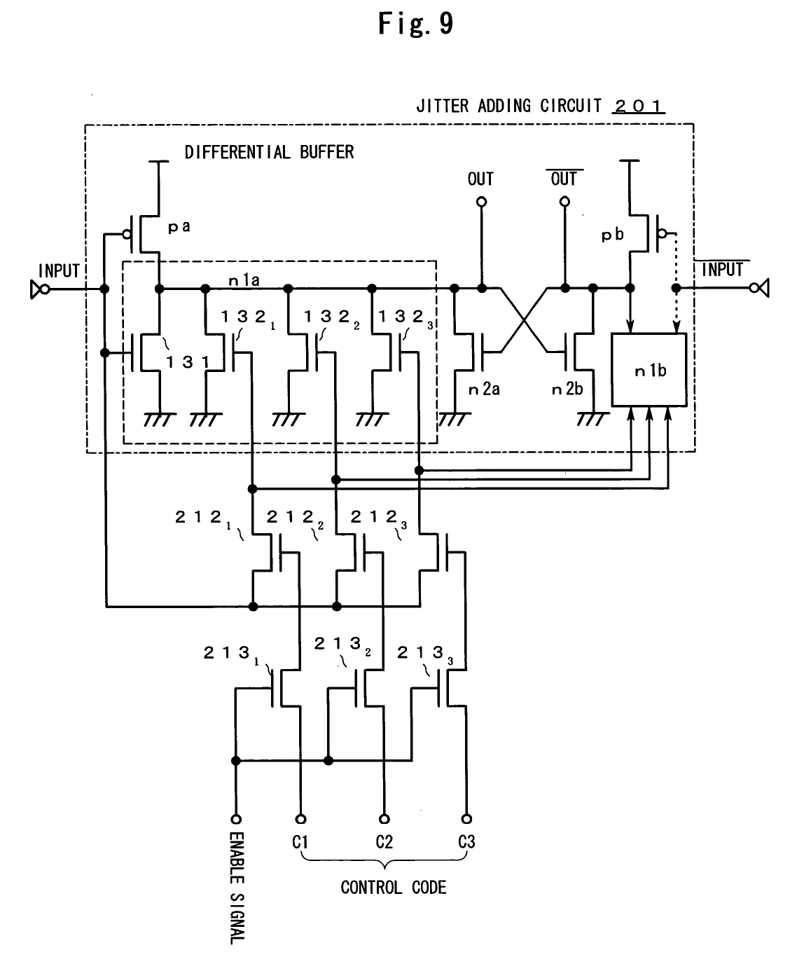

FIG. 9 shows another embodiment of the jitter adding circuit.

Note that constituent elements, out of those shown in FIG. 9, that are equivalent to the constituent elements shown in FIG. 6 are designated by the same reference numerals and symbols as those designating the constituent elements shown in FIG. 6, and description thereof will be omitted.

In a jitter adding circuit 201 shown in FIG. 9, a differential buffer is composed of pMOS transistors pa, pb and nMOS transistors n1a, nib, n2a, n2b. In FIG. 9, each of the nMOS transistors n1a, n1b is constituted of a fixed transistor 131 and three variable transistors 132₁ to 132₃ similarly to the nMOS transistor constituting the succeeding inverter shown in FIG. 6. Note that FIG. 9 shows only the nMOS transistor n1a in detail, and shows the nMOS transistor n1b as block but the detailed configuration thereof is equivalent to those of the nMOS transistor n1a.

When an appropriate control code is inputted to the jitter adding circuit 201 as structured above, nMOS transistors 212₁ to 212₃ and nMOS transistors 213₁ to 213₃ operate according to the control code, and among the three variable transistors 132₁ to 132₃ provided in each of the nMOS transistors n1a, n1b, those selected based on the control code can be made to contribute to the formation of an nMOS transistors n1 complimentarily coupled with the pMOS transistors pa, pb. Accordingly, the ratio of the size of the pMOS transistor pa and the total size of the nMOS transistors n1a, n2a, and the ratio of the size of the pMOS transistor pb and the total sizes of the nMOS transistors n1b, n2b can be changed at the same rate, which makes it possible to generate desired jitter at an output of the differential buffer.

Incidentally, when the jitter adding circuit 201 shown in FIG. 9 is operated as a differential buffer, the appropriate variable transistors 132 may be made to contribute to the formation of the nMOS transistor n1a so that the ratio of the size of the pMOS transistor pa and the total size of the nMOS transistors n1a, n2a becomes 2:1.

Further, instead of changing the size of the nMOS transistors n1a, n1b as described above, the size of the nMOS transistors n2a, n2b or the pMOS transistors pa, pb may be changed. Alternatively, the size of all of these transistors may be changed.

As described above, in the jitter adding circuit shown in FIG. 3, FIG. 6, or FIG. 9, jitter is generated by imbalance between the sizes of the pMOS transistor and the nMOS transistors constituting the complementary MOS circuit element represented by a buffer or inverter, the imbalance resulting from the change of the size of the pMOS transistor or the nMOS transistors constituting the jitter adding circuit. Therefore, in the jitter adding circuit in which a jitter adding function is incorporated in a buffer or inverter, it is of course acceptable to change the size of the pMOS transistor or change the size of both the nMOS transistor and the pMOS transistor instead of changing the size of the nMOS transistor.

Next, a method of diagnosing jitter tolerance of a circuit element forming a Tx block or an Rx block provided in an interconnect LSI will be described in more detail.

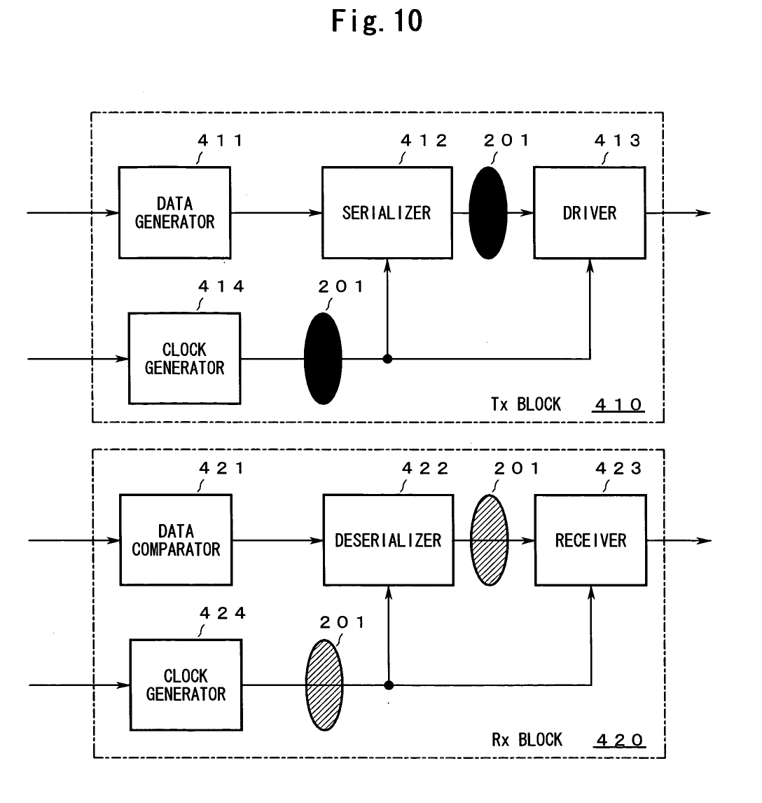

FIG. 10 shows an arrangement example of jitter adding circuits.

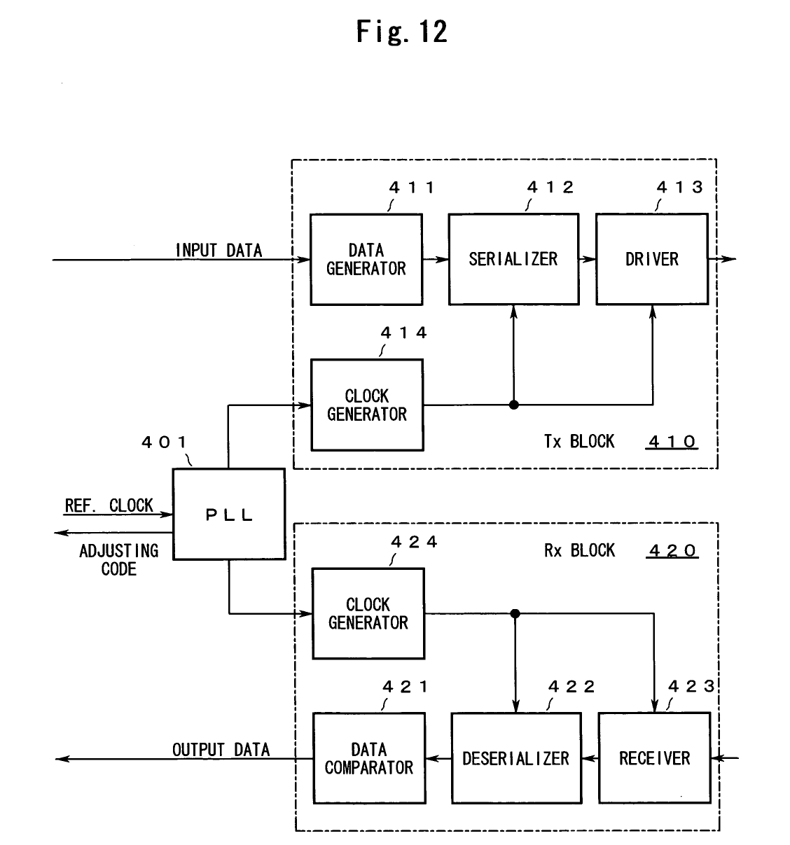

Note that constituent elements, among those shown in FIG. 10, that are equivalent to the constituent elements shown in FIG. 12 will be designated by the same reference numerals and symbols as those designating the constituent elements shown in FIG. 12, and description thereof will be omitted.

In a Tx block 410 shown in FIG. 10, jitter adding circuits 201 are disposed succeedingly to a clock generator 414 and on the boundary between a serializer 412 and a driver 413. Control codes are inputted to the jitter adding circuits 201 respectively, and an output signal of the Tx block 410 is monitored while desired jitter is generated, so that individual measurement of jitter tolerance of each circuit element forming the Tx block 410 is enabled.

Similarly, in the Rx block 420, the jitter adding circuits 201 are disposed succeedingly to a clock generator 424 and the boundary between a serializer 422 and a receiver 423. Control codes are inputted to these jitter adding circuits 201 respectively and an output signal of the Rx block 420 is monitored while desired jitter is generated, so that individual measurement of jitter tolerance of each circuit element forming the Rx block 420 is enabled.

Incidentally, instead of generating pseudo jitter by the jitter adding circuit that is a modified circuit of a buffer or inverter, as described in the above-described embodiments, a circuit that generates true jitter using a PLL may be mounted as the jitter adding circuit.

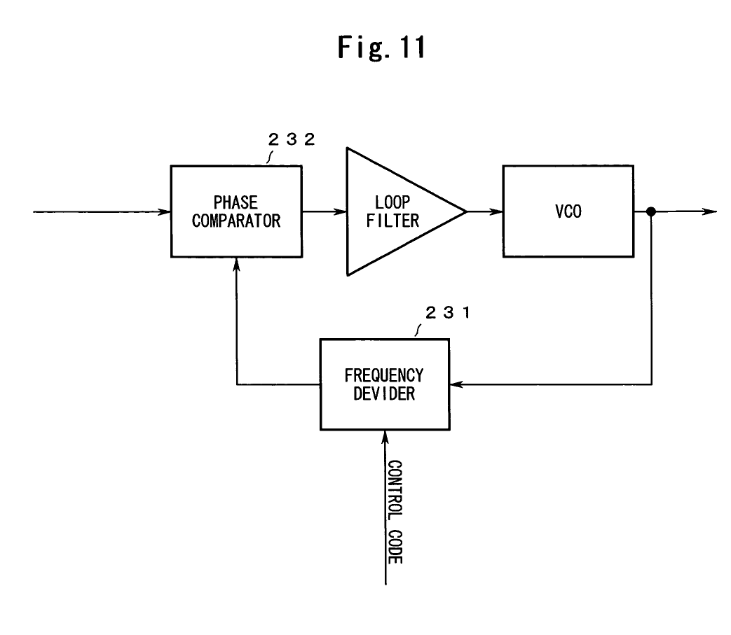

A possible example of such a jitter adding circuit is the structure, as shown in FIG. 11, such that a divider 231 frequency-divides an output signal according to a frequency division ratio determined based on control codes, and an obtained signal is inputted as a control input to a phase comparator 232.

The invention is not limited to the above embodiments and various modifications may be made without departing from the spirit and scope of the invention. Any improvement may be made in part or all of the components.

1. A method for diagnosing jitter tolerance of an LSI to be evaluated, the LSI being formed of a plurality of circuit blocks, the method comprising the steps of:
instructing, by inputting a control code thereto, a jitter adding circuit to generate a jitter of a desired magnitude, the jitter adding circuit being disposed precedingly to an intended circuit block and having a function of generating jitter of a magnitude designated by the control code; and
monitoring at least one output signal outputted from the LSI to be evaluated and judging whether or not a characteristic of the output signal satisfies a desired standard.

2. A method for diagnosing jitter tolerance, comprising the steps of:
selecting a complementary MOS circuit element which is disposed between an intended circuit block of a plurality of circuit blocks and a preceding circuit block to the intended circuit block, the plurality of circuit blocks forming an LSI to be evaluated;
replacing the selected complementary MOS circuit element by a jitter adding circuit that is a combination of a pMOS transistor and an nMOS transistor with a ratio of sizes thereof and that has a function equivalent to a function of the replaced complementary MOS circuit element when the ratio is fixed to an appropriate value, the ratio being changeable in accordance with an inputted ratio changing code; and
for diagnosis of jitter tolerance of the LSI to be evaluated, changing the ratio of the sizes of the pMOS and nMOS transistors within a predetermined range, the pMOS and nMOS transistors forming the jitter adding circuit disposed precedingly to the intended circuit block, the predetermined range being determined on a basis of a ratio of sizes of pMOS and nMOS transistors in the replaced complementary MOS circuit element corresponding to the jitter adding circuit; and
monitoring at least one output signal outputted from the LSI to be evaluated and judging whether or not a characteristic of the output signal satisfies a desired standard.

3. A jitter tolerance diagnostic apparatus comprising:
a jitter adding circuit disposed precedingly to at least one of a plurality of circuit blocks, for adding, to a signal received from a preceding circuit block, a jitter of a magnitude corresponding to an inputted control code, and for inputting the signal to a succeeding circuit block, the plurality of circuit blocks forming an LSI to be evaluated;
a jitter controlling unit instructing, by inputting a control code thereto, the jitter adding circuit to add a jitter of a desired magnitude, the jitter adding circuit disposed in correspondence with one of the plurality of circuit blocks forming the LSI; and
a monitoring unit monitoring at least one output signal outputted from the LSI to be evaluated and judging whether or not a characteristic of the output signal satisfies a desired standard.

4. The jitter tolerance diagnostic apparatus according to claim 3, wherein said jitter adding circuit comprises:
a complementary MOS circuit element formed of a pMOS transistor of a predetermined size and an nMOS transistor of a predetermined size different from that of the pMOS transistor; and
a size ratio changing unit changing, according to an inputted control code, a ratio of sizes of the pMOS transistor and the nMOS transistor which contribute to the formation of the complementary MOS circuit element.

5. The jitter tolerance diagnostic apparatus according to claim 3, wherein:
said jitter adding circuit comprises: a fixed transistor connected in series to a pMOS transistor forming one of a buffer and an inverter, and being an nMOS transistor of a predetermined size S to contribute to a function of the buffer or the inverter; a number m of variable transistors being nMOS transistors of a size Sᵢ(i=1 to m) and connected in parallel to the fixed transistor; and a number m of switches disposed in correspondence with the number m of variable transistors, each for determining according to a control code whether or not an input signal voltage is to be applied to a gate terminal of a corresponding variable transistor; and
said jitter controlling unit comprises: a control code generating unit generating a control code of m bits according to a desired jitter value; and a selecting unit selecting a circuit block from the at least one of plurality of circuit blocks and inputting control signals of bits forming the control codes, respectively to the number m of switches provided in a jitter adding circuit corresponding to the selected circuit block.
